(19) United States
(12) Patent Application Publication
(10) Pub. No.: US 2026/0252749 A1
(43) Pub. Date: Aug. 27, 2026

(54) SYSTEM AND METHOD FOR OPENBIM-BASED AUTOMATIC INTEGRATION OF IOT DEVICES INTO DIGITAL TWIN PLATFORMS

(71) Applicant: The Hong Kong University of Science and Technology, Hong Kong (CN)

(72) Inventors: Helen Hoi Ling KWOK, North Adelaide (AU); Chin Pang CHENG, Hong Kong (CN); Miu Ki YU, Hong Kong (CN)

(21) Appl. No.: 19/379,791

(22) Filed: Nov. 5, 2025

Related U.S. Application Data
(60) Provisional application No. 63/761,186, filed on Feb. 21, 2025.

(51) Int. Cl. G06F 30/13

(52) U.S. Cl. CPC G06F 30/13

(57) ABSTRACT

A system for integrating BIM and IoT data into a digital twin platform is provided, enabling real-time spatial monitoring, semantic referencing, and lifecycle management of building assets. The system comprises a BIM interface module, an IFC conversion module, a preprocessing module, and a data linking module. The BIM interface module receives external data to generate or update a BIM model. The IFC conversion module converts the BIM model into an IFC-compliant format with globally unique identifiers. The preprocessing module performs model federation and data normalization and includes subcomponents for geometry conversion to WebGL, semantic structuring, IoT spatial tagging, and level tagging. The data linking module serializes outputs, uploads them to object storage, and registers access URLs and attribute mappings in the platform database.

### CROSS-REFERENCE TO RELATED APPLICATIONS

The present application claims priority from a U.S. provisional patent application serial number 63/761,186 filed February 21, 2025, and the disclosure of which is incorporated by reference in its entirety.

### TECHNICAL FIELD

The present invention relates to digital twin and building information modeling (BIM) technologies; more specifically, it is directed to a system and method for automatically integrating Internet of Things (IoT) devices into a digital twin platform based on openBIM standards.

### BACKGROUND

In the evolving landscape of construction and facility management, the increasing complexity of building operations and the demand for real-time, data-driven decision-making have driven the widespread adoption of Internet of Things (IoT) technologies. IoT enables the connection of physical objects to the internet, allowing for real-time monitoring and control of physical assets.

To fully realize the value of IoT within built environments, the integration of IoT with Digital Twin technologies has become essential for optimizing energy efficiency, predictive maintenance, and overall operational performance. However, existing solutions often face challenges such as interoperability issues, inefficiencies in data synchronization, and difficulties in achieving real-time monitoring. Many systems also lack standardized methods for integrating Building Information Modeling (BIM) data with IoT applications, resulting in fragmented workflows and limited scalability.

Moreover, the absence of automated mechanisms for associating IoT devices with BIM elements continues to hinder the large-scale deployment of digital twin systems, particularly in multi-building or multi-organization scenarios. Therefore, there is a need for a system and method that enables automatic integration of IoT devices into digital twins, supporting consistent data synchronization, semantic alignment, and real-time operability.

### SUMMARY OF INVENTION

It is an objective of the present invention to provide a system and a method for automatically integrating Internet of Things (IoT) devices into digital twin platforms based on open-building information modeling (openBIM) standards, thereby addressing the aforementioned shortcomings and unmet needs in the state of the art.

In the present invention, a solution is provided to address the discussed limitations by automating the integration of IoT devices and digital twin technologies using openBIM technologies. The present invention automates the integration of IoT devices and BIM models within digital twin platforms. By assigning unique IDs to BIM components and converting them into openBIM format, the proposed system ensures seamless interoperability, reprocessing steps optimize data for storage in the digital twin platform. This automated process streamlines data synchronization, reduces manual effort, and enhances the overall efficiency of facility management operations.

In accordance with a first aspect of the present invention, a system for integrating BIM data with IoT data into a digital twin platform is provided, thereby enabling real-time spatial monitoring, semantic referencing, and lifecycle management of building assets within a digital twin environment. The system includes a BIM interface module, an industry foundation classes (IFC) conversion module, a preprocessing module, and a data linking module. The BIM interface module is configured to receive external geometric and semantic data and to generate or update a BIM model, wherein the BIM model comprises three-dimensional representations of building elements and associated semantic specifications. The IFC conversion module is configured to convert the BIM model into a format compliant with an IFC schema so as to obtain a converted IFC model and configured to assign globally unique identifiers (GUIDs) to the building elements. The preprocessing module configured to receive the converted IFC model from the IFC conversion module and to perform model federation and data normalization. The preprocessing module includes: a geometry conversion subcomponent configured to transform BIM geometry into a format compatible with WebGL based on the geometric representations contained in the converted IFC model; a semantic structuring subcomponent configured to extract and structure non-geometric metadata based on the semantic property sets contained in the converted IFC model; an IoT tagging subcomponent configured to compute centroid-based spatial tags for IoT-eligible building elements based on the mesh geometry derived from the federated IFC model; and a level tagging subcomponent configured to compute vertical placement information for IFC floor elements based on bounding box analysis of the floor-related geometry in the federated IFC model; and a data linking module configured to serialize geometric and semantic outputs from the preprocessing module, to upload the geometric and semantic outputs to an object storage of a digital twin platform, and to register access URLs and attribute mappings into a database schema of the digital twin platform.

In accordance with a second aspect of the present invention, a method for integrating BIM data with IoT data into a digital twin platform is provided, thereby enabling real-time spatial monitoring, semantic referencing, and lifecycle management of building assets within a digital twin environment. The method includes steps as follows: receiving, by a BIM interface module, external geometric and semantic data; generating or updating, by the BIM interface module, a BIM model comprising three-dimensional representations of building elements and associated semantic specifications; converting, by an IFC conversion module, the BIM model into a format compliant with the an IFC schema so as to obtain a converted IFC model; assigning, by the IFC conversion module, GUIDs to the building elements; receiving, by a preprocessing module, the converted IFC model from the IFC conversion module; performing, by the preprocessing module, model federation and data normalization, comprising: (1) transforming, by a geometry conversion subcomponent of the preprocessing module, BIM geometry into a format compatible with WebGL based on the geometric representations contained in the converted IFC model; (2) extracting and structuring, by a semantic structuring subcomponent of the preprocessing module, non-geometric metadata based on the semantic property sets contained in the converted IFC model; (3) computing, by an IoT tagging subcomponent of the preprocessing module, centroid-based spatial tags for IoT-eligible building elements based on the mesh geometry derived from the federated IFC model; and (4) computing, by a level tagging subcomponent of the preprocessing module, vertical placement information for IFC floor elements based on bounding box analysis of the floor-related geometry in the federated IFC model; serializing, by a data linking module, geometric and semantic outputs from the preprocessing module; uploading, by the data linking module, the geometric and semantic outputs to an object storage of a digital twin platform; and registering, by the data linking module, access URLs and attribute mappings into a database schema of the digital twin platform.

### BRIEF DESCRIPTION OF DRAWINGS

Embodiments of the invention are described in more details hereinafter with reference to the drawings, in which:

FIG. 1 illustrates a flow diagram of an automatic BIM model update synchronization process according to some embodiments of the present invention;

FIG. 2 shows a flow diagram of a BIM model preprocessing process according to some embodiments of the present invention;

FIG. 3 illustrates a flow diagram of an automatic IoT tagging process according to some embodiments of the present invention;

FIG. 4 illustrates a flow diagram of an automatic level tagging process according to some embodiments of the present invention;

FIG. 5 demonstrates how BIM model information is associated with the digital twin platform according to some embodiments of the present invention;

FIG. 6 demonstrates a multi-organization, multi-building, and multi-protocol data integration process for the digital twin platform according to some embodiments of the present invention; and

FIG. 7 shows a block diagram of a system and its interaction with a digital twin platform according to some embodiments of the present invention.

### DETAILED DESCRIPTION OF THE INVENTION

In the following description, systems and methods for automatically integrating Internet of Things (IoT) devices into a digital twin platform based on openBIM standards and the likes are set forth as preferred examples. It will be apparent to those skilled in the art that modifications, including additions and/or substitutions may be made without departing from the scope and spirit of the invention. Specific details may be omitted so as not to obscure the invention; however, the disclosure is written to enable one skilled in the art to practice the teachings herein without undue experimentation.

The present invention provides a solution for automating the integration of IoT devices into digital twin platforms using openBIM standards. The solution, referred to as AutoSync, enables semantic alignment, spatial referencing, and real-time data synchronization between BIM models and IoT data sources. AutoSync includes processes for BIM model preprocessing, automatic tagging of elements and levels, and structured linkage of geometric and semantic data to the digital twin platform. This approach supports scalable integration across diverse buildings and systems, addressing the interoperability and fragmentation issues found in existing solutions.

The following first describes the technical architecture and operational principles of the present invention, AutoSync solution, and then presents a hardware configuration capable of supporting AutoSync solution.

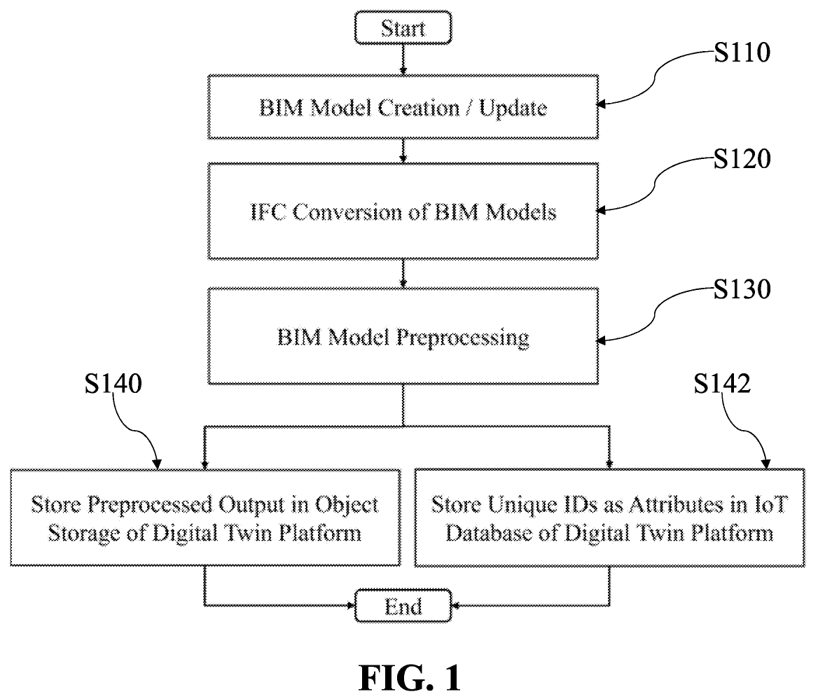

FIG. 1 illustrates a flow diagram of an automatic BIM model update synchronization process according to some embodiments of the present invention. The process includes steps S110, S120, S130, S140, and S142. It begins with the creation or update of a BIM model at step S110. The BIM model can be a 3D representation of a building or infrastructure project, containing detailed information about its components and material specifications. Unique identifiers (IDs) are assigned to the individual components and elements within the BIM model.

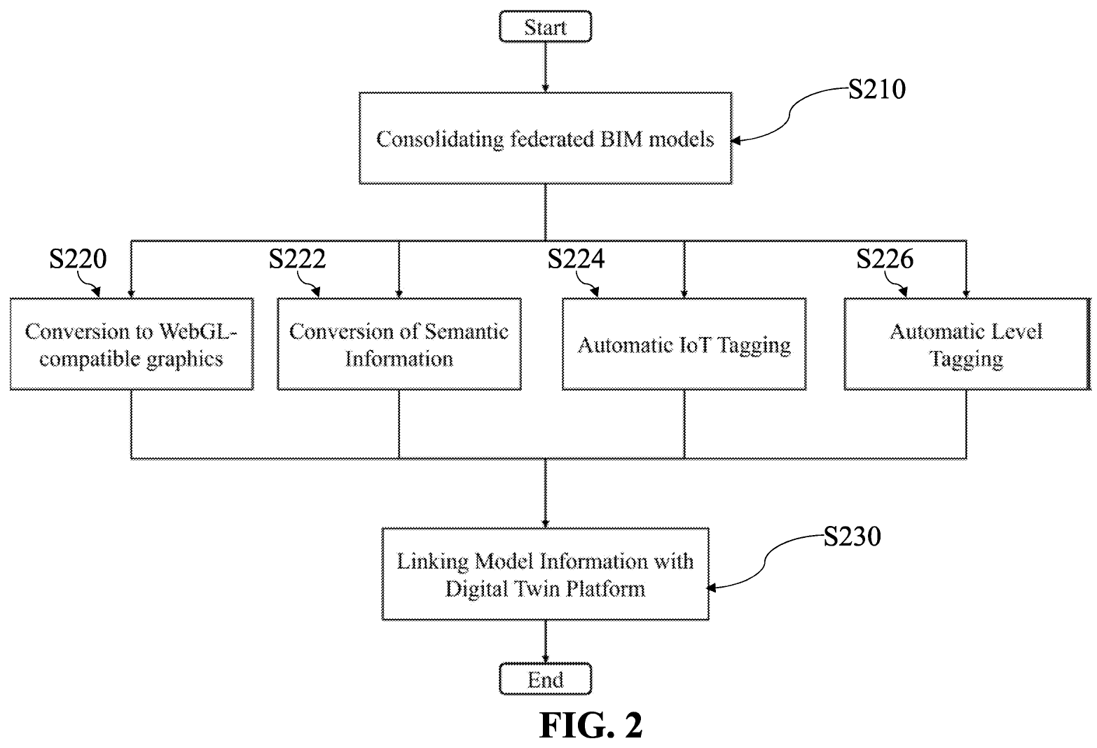

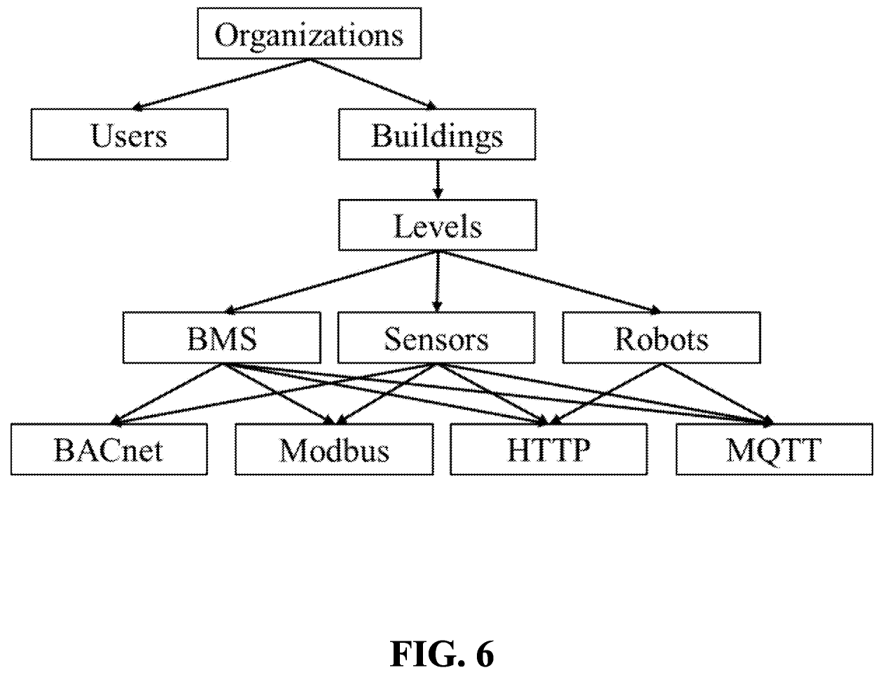

At step S120, the BIM model is converted into an Industry Foundation Classes (IFC) format. IFC is an open standard file format for sharing information about building and construction projects, and this conversion ensures interoperability between different software tools and platforms. At step S130, the converted IFC model undergoes preprocessing. This preprocessing step is illustrated in FIG. 2, which shows a flow diagram of a BIM model preprocessing process according to some embodiments of the present invention. The preprocessing includes the conversion of WebGL-compliant graphics, conversion of semantic information, and automatic tagging of IoT devices and levels. At step S140, the preprocessed BIM model data is stored in the object storage of the digital twin platform. At step S142, the unique IDs are stored as attributes in the IoT database of the digital twin platform. The structure of the platform is illustrated in FIG. 6, which demonstrates a multi-organization, multi-building, and multi-protocol data integration process for the digital twin platform according to some embodiments of the present invention. The digital twin platform serves as a central repository for facility-related data, enabling downstream applications such as monitoring, analytics, and maintenance planning.

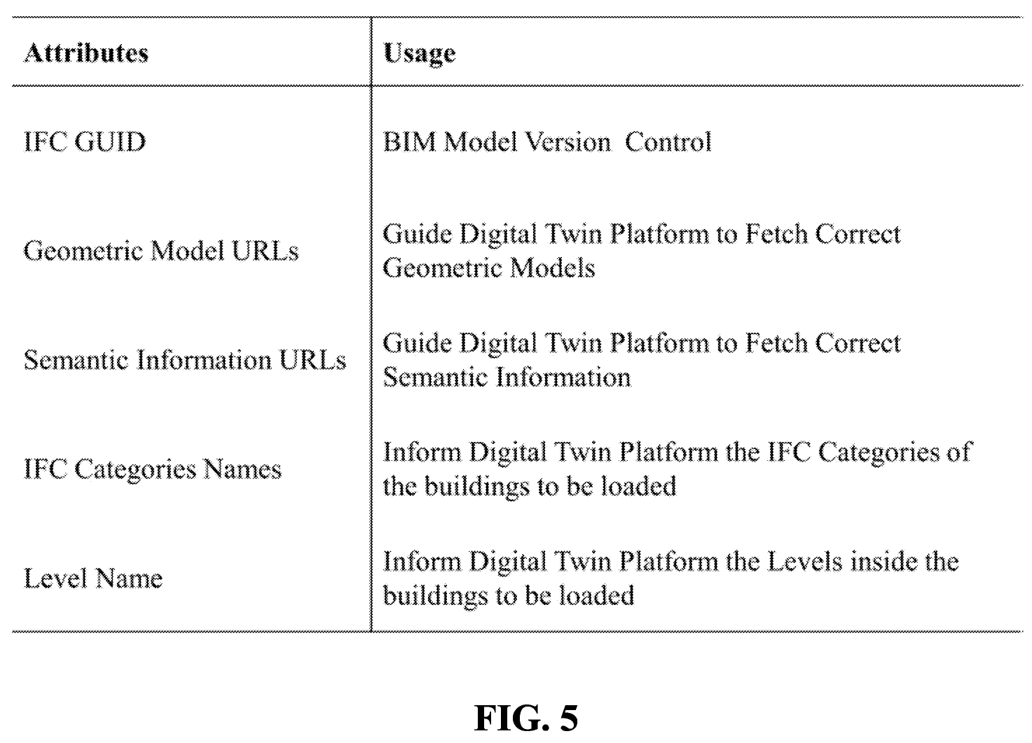

FIG. 2 presents a flow diagram of a BIM model preprocessing process according to some embodiments of the present invention, including steps S210, S220, S222, S224, S226, and S230. This process corresponds to step S130 in FIG. 1, which involves preprocessing the converted BIM model prior to integration with the digital twin platform. At step S210, various BIM models from different sources, referred to as federated models, are consolidated into a unified representation. This consolidation step ensures consistency and compatibility for further processing. At step S220, since BIM models often contain complex three-dimensional geometry, the geometry is converted into a format compatible with WebGL. This web-based graphics format allows for efficient visualization and interaction within a browser environment. At step S222, semantic information about building elements, including material types, properties, and functions, is converted into a structured format that is suitable for integration with the digital twin platform. At step S224, to support real-time data collection and integration, objects within the BIM model that can be associated with IoT devices are automatically identified and tagged. At step S226, building levels within the BIM model are automatically located in a manner similar to IoT tagging. This step enables spatial referencing and provides contextual meaning to the associated data within the digital twin platform. At step S230, the processed BIM data, including geometric and semantic information, is linked to the digital twin platform. This linkage is further illustrated in FIG. 5, which demonstrates how BIM model information is associated with the digital twin platform according to some embodiments of the present invention. This integration allows the platform to utilize the BIM data for various purposes such as visualization, analytics, and facility operations.

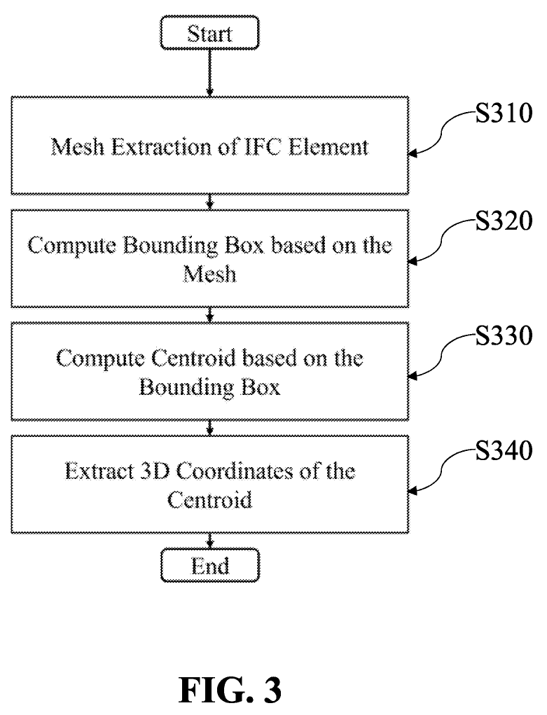

FIG. 3 illustrates a flow diagram of an automatic IoT tagging process according to some embodiments of the present invention. This process corresponds to step S224 in FIG. 2, which involves the automatic identification of IoT-tagged elements within the BIM model. The process includes steps S310, S320, S330, and S340. At step S310, a mesh representation of an IFC element is extracted. This step involves converting the geometric information of the building element into a mesh composed of vertices and faces. At step S320, once the mesh has been extracted, a bounding box is computed. The bounding box is a rectangular volume that tightly encloses the entire mesh and defines its spatial limits. At step S330, the centroid of the bounding box is computed. The centroid represents the geometric center of the box and corresponds to the average position of all spatial points within the bounding volume. At step S340, the three-dimensional coordinates of the centroid are extracted. These coordinates define the x, y, and z positions of the centroid in 3D space and are used to represent the spatial location of the associated IoT device within the digital twin platform.

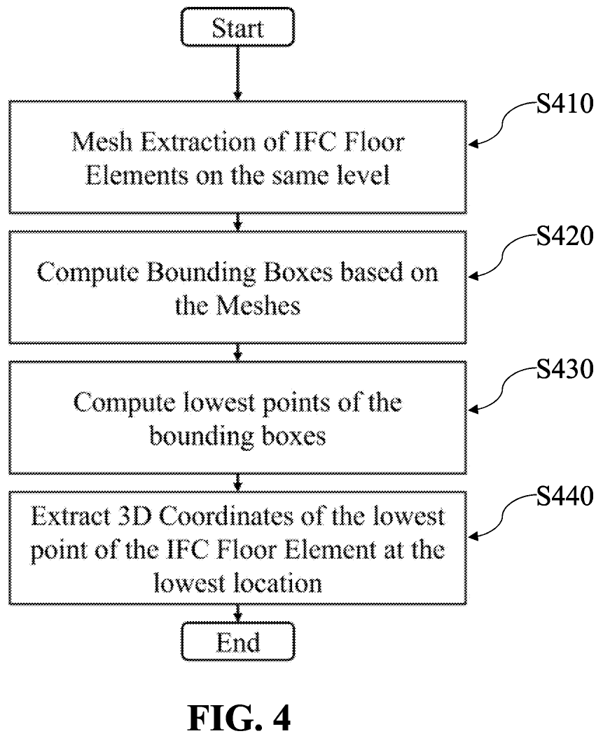

FIG. 4 illustrates a flow diagram of an automatic level tagging process according to some embodiments of the present invention. This process corresponds to step S226 in FIG. 2, which involves the automatic identification of building levels within the BIM model. The process includes steps S410, S420, S430, and S440. At step S410, the process extracts the mesh data for all IFC Floor Elements that are located on the same level, such as elements on the same floor of a building. This mesh data represents the three-dimensional geometry of each floor element. At step S420, for each extracted mesh, a bounding box is computed. The bounding box is a rectangular volume that tightly encloses the entire geometry of the mesh. At step S430, the process determines the point with the lowest z-coordinate from each bounding box. The z-axis in this context represents vertical height in a standard Cartesian coordinate system. The identified point is considered the lowest point of the corresponding floor element. At step S440, the three-dimensional coordinates of the lowest point are extracted. These coordinates, expressed as x, y, and z values, represent the lowest location of the IFC Floor Element and are used to establish level-based spatial referencing within the digital twin platform.

FIG. 5 illustrates the linkage between BIM model information and the digital twin platform. The illustration in FIG. 5 further elaborates on steps S140 and S142 in FIG. 1. The attributes shown, including IFC GUID, geometric model URLs, semantic information URLs, IFC category names, and level names, represent the structured metadata and access pointers that are either stored in the object storage (i.e., step S140) or as database attributes within the digital twin platform (i.e., step S142). These data elements support model version control, semantic referencing, and multi-level spatial organization for downstream digital twin applications.

The IFC GUID (Industry Foundation Classes Global Unique Identifier) is a unique identifier assigned to each BIM (Building Information Model) object. This attribute is crucial for version control, ensuring that the correct version of the model is used within the digital twin. Geometric model URLs point to the locations of the geometric models (3D representations) of the building or object. The digital twin platform uses these URLs to retrieve the accurate geometric information needed for visualization and analysis. Similar to the geometric model URLs, semantic information URLs provide access to the semantic information associated with the building or object. Semantic information includes data like materials, dimensions, equipment types, and other relevant attributes. This information is essential for understanding the object's characteristics and behavior. IFC categories define the types of building elements (e.g., IFCWALL, IFCSLAB, IFCBUILDINGELEMENTPROXY, etc.). This attribute informs the digital twin platform about the specific categories present in the building models, allowing for efficient filtering and analysis of the data. The level names specify the different floors or levels within the building.

The discussed information helps the digital twin platform organize and visualize the building's structure accurately. For example, these attributes are generated and stored by the data linking module of a system (e.g., a system 700 discussed in the subsequent descriptions). During execution of step S140, the geometric and semantic output files resulting from the BIM model preprocessing are uploaded to object storage and their corresponding access URLs are generated. These URLs are then written into metadata tables within the digital twin platform. In step S142, the IFC GUIDs of building elements, along with their associated category and level information, are stored as attributes within the platform’s IoT database. This is performed through a schema mapping operation that binds each unique identifier to its semantic and spatial context.

FIG. 6 illustrates the data organization and system architecture of the digital twin platform that receives and utilizes the processed outputs described in FIG. 1 through FIG. 5. The layered structure in FIG. 6 reflects how preprocessed BIM data, semantic tags, geometric models, and IoT associations are organized and accessed by various subsystems within the platform.

In FIG. 6, a multi-layered structure is presented that allows for the integration of data from various sources, including different organizations, buildings, and systems in a digital twin platform. This data can then be used to create a comprehensive digital twin that provides insights and enables optimization of building operations and services. Organizations represent the overarching entities or organizations that own and operate the buildings and systems within the digital twin. Users include information about the people who interact with the buildings and systems, such as their roles, permissions, and preferences. Buildings represent the building information, e.g., names, addresses, building types, etc. Levels represent different levels within a building, with each level having its own set of data and systems. BMS refers to equipment from building management systems, which are crucial for facility management and maintenance. Sensors include various sensors that collect data about the environment, such as temperature, humidity, occupancy, noise, and air quality. Robots represent autonomous robots or drones that operate within the building, collecting data or performing tasks.

The multi-layered architecture shown in FIG. 6 is designed to consume and operationalize the data generated by earlier steps, including BIM model preprocessing (i.e., FIG. 2), IoT tagging (i.e., FIG. 3), level tagging (i.e., FIG. 4), and attribute linkage (i.e., FIG. 5). It represents the platform-level implementation that enables data-driven operation, monitoring, and optimization across multiple organizations and buildings.

The above technical solution or technical service may be implemented by the following hardware configuration.

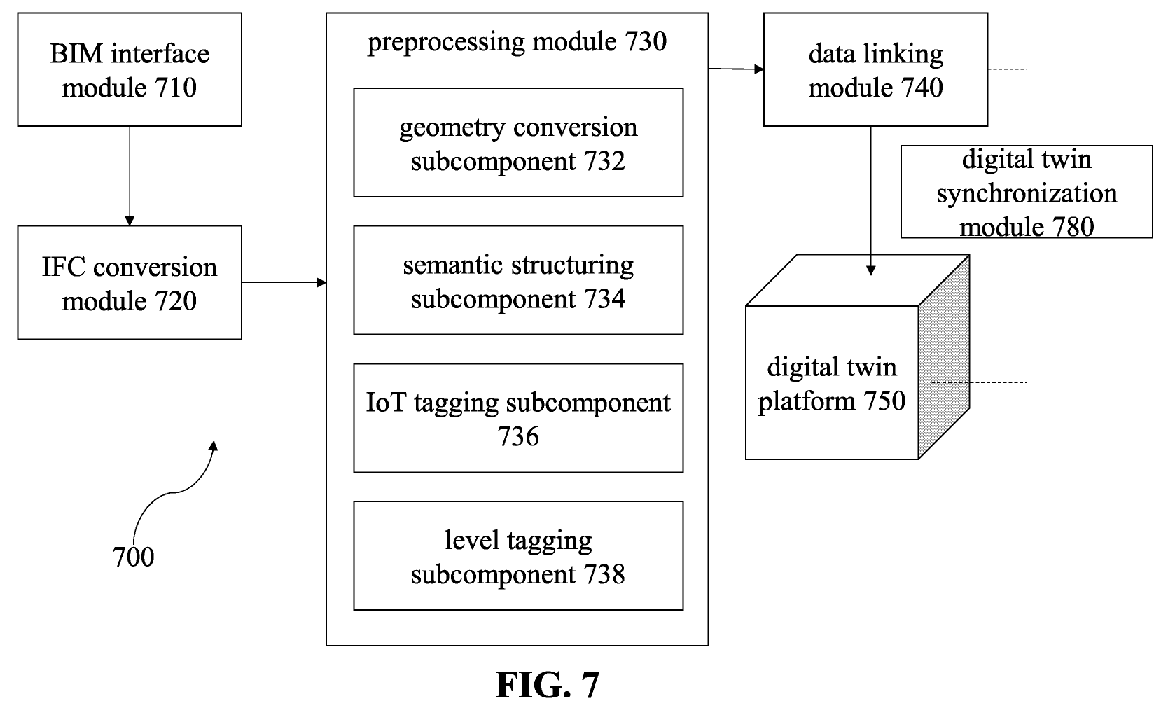

FIG. 7 shows a block diagram of a system 700 and its interaction with a digital twin platform 750 according to some embodiments of the present invention. A system 700 is configured to automatically synchronize BIM data and IoT device data into a digital twin platform 750, thereby enabling real-time spatial monitoring, semantic referencing, and lifecycle management of building assets within a digital twin environment. The system 700 include a BIM interface module 710, an IFC conversion module 720, a preprocessing module 730, and a data linking module 740. In some embodiments, the system 700 may be implemented across one or more computing environments selected from cloud servers, edge computing units, or virtualized containers, in which each may include one or more processors configured to execute software instructions associated with modules of the system 700.

The BIM interface module 710 is configured to either (i) receive external geometric and semantic data streams and generate a building information model based on the received data; or (ii) receive a pre-existing BIM model authored externally and convert it into a format compatible with the internal processing architecture of system 700. In this regard, the operations of the BIM interface module 710 correspond to step S110 in FIG. 1, which involves the creation or update of a BIM model. The generated or converted BIM model includes three-dimensional representations of building or infrastructure components and associated semantic specifications, including but not limited to material properties, element types, and structural roles. The BIM interface module 710 is further configured to assign or preserve unique IDs for each building element to support traceability and cross-module data integration. For example, unique IDs assigned to building elements may be represented as structured alphanumeric strings, such as those conforming to the IFC schema. Each ID is persistently associated with a corresponding geometry node and semantic object in the system database and is machine-readable and non-ambiguous within the scope of the model. These identifiers enable cross-referencing between geometric representations, metadata, and live IoT data bindings. In one embodiment, the BIM interface module 710 is further configured to preserve pre-existing element identifiers or to generate provisional alphanumeric tags for building elements prior to subsequent IFC conversion, so as to maintain traceability between geometric and semantic data across processing stages.

It is noted that the operations performed by the BIM interface module 710 involve structured data processing steps that cannot be performed manually, such as schema-based parsing, machine-generated unique identifiers, and memory-based object linking. These steps require executable logic and interaction with computing resources.

The IFC conversion module 720 is configured to transform a received building information model into a format compliant with the IFC schema, thereby enabling interoperability across different BIM authoring tools and digital twin platforms (e.g., the digital twin platform 750). The operations of the IFC conversion module 720 correspond to step S120 in FIG. 1, which involves converting the BIM model into an IFC format to support downstream processing. The IFC conversion module 720 is configured to parse the model content, extract the geometric representations and semantic metadata of individual building elements, and re-encode them into structured IFC entities in accordance with openBIM-based standards. In some embodiments, the IFC conversion module 720 may perform type mapping, property normalization, and model restructuring to align the input data with the IFC schema requirements. The IFC conversion module 720 may also assign or validate GUIDs for each building element in the converted model. These GUIDs serve as persistent references that enable cross-platform traceability, version control, and linkage with external datasets such as IoT device mappings or facility databases. The resulting IFC model is a machine-readable, schema-conformant representation that preserves both the spatial structure and the semantic richness of the original BIM data.

The conversion process by the IFC conversion module 720 involves executable parsing logic, structured schema mapping, and data serialization operations that require computing resources, and is therefore carried out by machine-executable components such as the IFC conversion module 720.

The preprocessing module 730 is configured to perform BIM model preprocessing as illustrated in FIG. 2, including model federation at step S210 and data integration with the digital twin platform at step S230. The preprocessing module 730 further includes several subcomponents configured to perform intermediate steps, including geometry conversion at step S220, semantic structuring at step S222, IoT candidate tagging at step S224, and level tagging at step S226.

In some embodiments, the preprocessing module 730 is configured to execute step S210 in FIG. 2, which involves consolidating various BIM models from different sources, commonly referred to as federated models, into a unified IFC representation. This operation includes parsing and interpreting geometric and semantic data from each source model, resolving format inconsistencies, and merging overlapping or nested structures into a coherent, machine-readable schema.

The preprocessing module 730 includes a geometry conversion subcomponent 732, a semantic structuring subcomponent 734, an IoT tagging subcomponent 736, and a level tagging subcomponent 738. The resulting federated model serves as the normalized input for subsequent preprocessing operations performed by the subcomponents, which are responsible for geometry conversion, semantic structuring, IoT candidate tagging, and level tagging, respectively. By establishing data consistency and structural alignment at this stage, the preprocessing module 730 allows downstream modules to operate on a unified and contextually valid model representation.

For example, the geometry conversion subcomponent 732 is configured to convert complex BIM geometry into a format compatible with WebGL for efficient web-based visualization (as described in step S220). The semantic structuring subcomponent 734 is configured to extract and structure semantic information such as materials, functions, and properties for downstream integration (as described in step S222). The IoT tagging subcomponent 736 is configured to identify BIM objects that can be associated with IoT devices (as described in step S224). The level tagging subcomponent 738 is configured to detect and annotate building levels within the BIM model (as described in step S226).

The geometry conversion subcomponent 732 is configured to execute step S220 in FIG. 2, which involves transforming the geometric representation of BIM elements into a format compatible with WebGL. The geometry conversion subcomponent 732 receives as input the IFC-based geometry of each building element (e.g., the converted IFC model from the IFC conversion module 720), parses its structural components such as faces, edges, and vertices, and converts them into a mesh format suitable for real-time web-based rendering. The output is a set of optimized, WebGL-compliant geometry files that support lightweight visualization within the digital twin platform 750.

The semantic structuring subcomponent 734 is configured to execute step S222 in FIG. 2, which involves extracting and organizing the semantic information embedded in BIM elements. The semantic structuring subcomponent 734 receives as input IFC elements (e.g., the converted IFC model from the IFC conversion module 720) that contain non-geometric attributes such as material specifications, functional classifications, and property sets. The semantic structuring subcomponent 734 parses these attributes, normalizes them into a structured metadata format, and generates output that is compatible with the digital twin platform's semantic data model. The resulting semantic records enable downstream modules to perform data filtering, querying, and interpretation based on building-specific metadata.

The IoT tagging subcomponent 736 is configured to execute the operations of step S224 in FIG. 2 and the detailed sequence shown in FIG. 3, including steps S310, S320, S330, and S340. The IoT tagging subcomponent 736 is responsible for generating spatial tags for building elements in the BIM model that are eligible for IoT integration.

The IoT tagging subcomponent 736 executes step S310 in FIG. 3 by receiving as input an IFC element (e.g., the converted IFC model from the IFC conversion module 720) that has been identified as an IoT candidate. The IoT tagging subcomponent 736 accesses the geometric definition of the element and converts it into a mesh representation consisting of vertices and faces. The output of this step is a discrete mesh model suitable for geometric analysis.

The IoT tagging subcomponent 736 executes step S320 in FIG. 3 by computing a bounding box for the mesh of the discrete mesh model generated in the previous step. This step takes the mesh as input and calculates a minimum-volume rectangular box that tightly encloses the mesh geometry. The bounding box is represented by its corner coordinates and dimensional extents.

The IoT tagging subcomponent 736 executes step S330 in FIG. 3 by using the bounding box as input to calculate its centroid. The centroid is computed as the geometric center of the box by the IoT tagging subcomponent 736 and represents the average location of all enclosed points. The output of this step is a 3D point expressed in x, y, and z coordinates within the BIM spatial reference system.

The IoT tagging subcomponent 736 is further configured to execute step S340 in FIG. 3 by extracting the centroid coordinates and packaging them into a structured spatial tag. The final output of the IoT tagging subcomponent 736 is a data object that maps the IFC element’s identifier to its corresponding centroid coordinates. This spatial tag can be stored, indexed, and associated with IoT device data in subsequent stages of the applied process.

The IoT tagging subcomponent 736 executes these steps using geometry parsing engines, mesh processors, spatial calculation routines, and data structuring logic. These processes operate on structured BIM data formats and produce machine-readable outputs for integration into the digital twin platform 750.

The level tagging subcomponent 738 is configured to execute the operations of step S226 in FIG. 2 and the process illustrated in FIG. 4, including steps S410, S420, S430, and S440. The level tagging subcomponent 738 is responsible for determining the vertical placement of building elements by identifying the lowest point of each IFC Floor Element, thereby enabling floor-level annotation and spatial referencing within the BIM model.

The level tagging subcomponent 738 executes step S410 in FIG. 4 by receiving as input a set of IFC elements (e.g., the converted IFC model from the IFC conversion module 720) categorized as floor-related, such as slabs or structural platforms. The level tagging subcomponent 738 extracts the mesh geometry of each element, which consists of polygonal faces representing the floor surface. The output of this step is a mesh dataset for each floor element.

The level tagging subcomponent 738 executes step S420 in FIG. 4 by processing the mesh geometry of each floor element to compute a bounding box. The bounding box is a rectangular volume that tightly encloses the mesh and is defined by its minimum and maximum coordinates along each spatial axis. The output is a bounding box object representing the spatial limits of each floor element.

The level tagging subcomponent 738 executes step S430 in FIG. 4 by analyzing the bounding box and identifying the point with the lowest z-coordinate. This computation assumes a Cartesian coordinate system in which the z-axis represents vertical height, allowing the lowest point to indicate the base elevation of the floor element. The output is a single 3D coordinate (x, y, z) that represents the element’s lowest vertical position.

The level tagging subcomponent 738 executes step S440 in FIG. 4 by assigning the extracted lowest point as the floor tag of the corresponding IFC Floor Element. The final output of the level tagging subcomponent 738 is a data record that maps each floor element's identifier to its computed vertical position. This data is used to support level-aware organization and visualization in the digital twin platform 750.

The level tagging subcomponent 738 performs these operations using mesh analyzers, bounding box computation routines, coordinate extraction logic, and structured tagging algorithms. The outputs are machine-readable and serve as spatial references for classifying building elements within hierarchical floor levels.

To support integration of BIM data into a digital twin platform, the preprocessing module 730 is designed to selectively target key categories of information that are essential for real-time visualization, semantic interpretation, and contextual analytics. The choice of geometry conversion, semantic structuring, IoT candidate tagging, and level tagging as primary preprocessing operations reflects the technical requirements of downstream modules that rely on accurate geometric representation, domain-specific metadata, spatial device mapping, and hierarchical floor-level organization. These four data domains were selected because they collectively represent the minimum viable set of information needed to support core digital twin functionalities such as web-based 3D rendering, sensor-data overlay, and level-aware operations across buildings. By focusing on these dimensions, the preprocessing module 730 enables efficient and scalable transformation of static BIM models into dynamically operational digital twin environments.

The preprocessing module 730 operates each subcomponent using machine-executable logic, such as geometry parsing, property mapping, or spatial inference, and prepares the processed data for linking with the digital twin platform 750 as described in step S230. The preprocessing module 730 aggregates the outputs generated by the geometry conversion subcomponent 732, the semantic structuring subcomponent 734, the IoT tagging subcomponent 736, and the level tagging subcomponent 738. These outputs include WebGL-compliant geometric representations, structured semantic metadata, spatial coordinates of IoT-mapped elements, and floor-level annotations. The preprocessing module 730 organizes this information into a set of data objects or metadata records that are compatible with the storage and retrieval structure of the digital twin platform 750, enabling the platform to access, render, and semantically interpret the building model and its associated device mappings.

The federation process requires executable logic for model parsing, conflict resolution, schema mapping, and data serialization, due to the structural complexity and heterogeneity of input BIM models. These operations involve high-volume and high-complexity data transformations, and are therefore carried out by the preprocessing module 730 using system-level computational resources.

The data linking module 740 is configured to execute steps S140 and S142 in FIG. 1, which involve storing preprocessed BIM data and linking it to a digital twin platform 750. The data linking module 740 receives as input the outputs generated by the preprocessing module 730, including WebGL-compliant geometry files, structured semantic metadata, spatially tagged IoT elements, and level annotations.

In step S140, the primary objective is to store the preprocessed geometric and semantic data into the object storage of the digital twin platform 750 so that they can be accessed by other components within the digital twin platform 750 for visualization and analysis. To achieve this, the data linking module 740 serializes the geometric and semantic outputs into structured data objects. These objects may include 3D mesh files in formats such as glTF, JSON, or other WebGL-compliant-based geometry, as well as semantic metadata formatted in JSON, XML, or any other machine-readable structures/documents. The data linking module 740 organizes these data objects by associating them with their respective building elements and uploads them to the object storage of the digital twin platform 750 using predefined storage interfaces or API endpoints. Upon upload, the data linking module 740 generates access URLs for each stored object, which are registered for platform-wide use within the digital twin platform 750.

In step S142, the goal is to establish searchable and traceable associations between building element identifiers and their corresponding metadata within the database of the digital twin platform 750. To this end, the data linking module 740 constructs a set of attribute mappings that associate each building element’s unique identifier, such as an IFC GUID, with its corresponding metadata. This metadata may include geometry file URLs, semantic tags, IFC category names, and level identifiers. The data linking module 740 formats these associations to match the schema used by the internal database of the digital twin platform 750 and writes the resulting records into appropriate tables or collections for query and retrieval purposes.

The data linking module 740 operates using schema mapping routines, metadata indexers, data object packaging logic, and API-based storage connectors. These components enable the structured transition of BIM-derived data from the preprocessing stage into the system architecture of the digital twin platform 750, thereby supporting consistent retrieval, rendering, and semantic referencing across multiple platform layers.

In some embodiments, the system 700 may further include a digital twin synchronization module 780 configured to maintain live operational coherence between the system-generated BIM data and the dynamic state of the digital twin platform 750. The digital twin synchronization module 780 is operatively coupled between the data linking module 740 and the digital twin platform 750. While the data linking module 740 is responsible for initial data upload and attribute mapping during steps S140 and S142, the synchronization module 780 monitors for updates, changes, or new inputs within the digital twin platform 750 that may affect existing model representations. The digital twin synchronization module 780 retrieves updated content, such as revised geometric models, modified semantic data, or newly tagged IoT elements, and performs incremental updates to maintain alignment between the digital twin platform 750 and the data state within system 700. The digital twin synchronization module 780 may also trigger downstream processes such as re-indexing or re-mapping when significant structural or semantic changes are detected. The digital twin synchronization module 780 operates using platform-facing APIs, differential comparison routines, and real-time event listeners to support continuous consistency across the platform architecture.

Upon receiving and registering data transmitted from system 700, the digital twin platform 750 stores and organizes a variety of structured content, including WebGL-compliant geometric models, semantic metadata, IoT device associations, and spatial floor-level annotations. These datasets are indexed and cross-linked within the internal schema of the digital twin platform 750, enabling them to be dynamically queried, visualized, and integrated with real-time operational data.

For example, one use case involves real-time facility monitoring, in which spatially tagged IoT data such as temperature, occupancy, or air quality is rendered in 3D through the geometry files uploaded by the data linking module 740. A building manager may visually inspect sensor conditions floor by floor and identify rooms with abnormal readings using the level information and IFC categories stored in the digital twin platform’s database. In another scenario, the digital twin platform 750 may support maintenance scheduling and asset tracking. Because each BIM element is linked with a persistent identifier (e.g., IFC GUID) and semantic description, the system can be used to locate specific equipment (such as an HVAC unit or fire damper), retrieve its service history, and flag it for inspection based on sensor data trends. These platform-level functions rely directly on the structured data pipeline established through the modules of the system 700.

Compared to conventional approaches where IoT data and BIM models are processed in isolated systems or require extensive manual configuration, the solution described herein offers substantial technical improvements in automation, scalability, and semantic integration. By automatically associating IoT devices with spatially and semantically structured BIM elements, the system 700 eliminates the need for manual tagging, device binding, and geometry interpretation, which are error-prone and labor-intensive in traditional workflows. The use of unique identifiers (e.g., IFC GUIDs), floor-level tagging, and structured geometry outputs enables precise localization and cross-referencing within the digital twin platform 750, thereby improving the accuracy and responsiveness of building operations. As a result, actions such as fault detection, maintenance routing, and environmental monitoring can be performed more efficiently, with reduced latency and higher reliability across multi-building or multi-floor deployments.

The functional units and modules of the systems and methods in accordance with the embodiments disclosed herein may be implemented using computing devices, computer processors, or electronic circuitries including but not limited to application specific integrated circuits (ASIC), field programmable gate arrays (FPGA), microcontrollers, and other programmable logic devices configured or programmed according to the teachings of the present disclosure. Computer instructions or software codes executing in the computing devices, computer processors, or programmable logic devices can readily be prepared by practitioners skilled in the software or electronic art based on the teachings of the present disclosure.

All or portions of the methods in accordance with the embodiments may be executed in one or more computing devices including server computers, personal computers, laptop computers, mobile computing devices such as smartphones and tablet computers.

The embodiments may include computer storage media, transient and non-transient memory devices having computer instructions or software codes stored therein, which can be used to program or configure the computing devices, computer processors, or electronic circuitries to perform any of the processes of the present invention. The storage media, transient and non-transient memory devices can be included, but are not limited to, floppy disks, optical discs, Blu-ray Disc, DVD, CD-ROMs, and magneto-optical disks, ROMs, RAMs, flash memory devices, or any type of media or devices suitable for storing instructions, codes, and/or data.

Each of the functional units and modules in accordance with various embodiments also may be implemented in distributed computing environments and/or Cloud computing environments, wherein the whole or portions of machine instructions are executed in distributed fashion by one or more processing devices interconnected by a communication network, such as an intranet, Wide Area Network (WAN), Local Area Network (LAN), the Internet, and other forms of data transmission medium.

The foregoing description of the present invention has been provided for the purposes of illustration and description. It is not intended to be exhaustive or to limit the invention to the precise forms disclosed. Many modifications and variations will be apparent to the practitioner skilled in the art.

The embodiments were chosen and described in order to best explain the principles of the invention and its practical application, thereby enabling others skilled in the art to understand the invention for various embodiments and with various modifications that are suited to the particular use contemplated.

What is claimed is:

1. A system for integrating building information modeling (BIM) data with Internet of Things (IoT) data into a digital twin platform, thereby enabling real-time spatial monitoring, semantic referencing, and lifecycle management of building assets within a digital twin environment, the system comprising:
a BIM interface module configured to receive external geometric and semantic data and to generate or update a BIM model, wherein the BIM model comprises three-dimensional representations of building elements and associated semantic specifications;
an industry foundation classes (IFC) conversion module configured to convert the BIM model into a format compliant with an IFC schema so as to obtain a converted IFC model and configured to assign globally unique identifiers (GUIDs) to the building elements;
a preprocessing module configured to receive the converted IFC model from the IFC conversion module and to perform model federation and data normalization, wherein the preprocessing module comprises:
a geometry conversion subcomponent configured to transform BIM geometry into a format compatible with WebGL based on the geometric representations contained in the converted IFC model;
a semantic structuring subcomponent configured to extract and structure non-geometric metadata based on the semantic property sets contained in the converted IFC model;
an IoT tagging subcomponent configured to compute centroid-based spatial tags for IoT-eligible building elements based on the mesh geometry derived from the federated IFC model; and
a level tagging subcomponent configured to compute vertical placement information for IFC floor elements based on bounding box analysis of the floor-related geometry in the federated IFC model; and
a data linking module configured to serialize geometric and semantic outputs from the preprocessing module, to upload the geometric and semantic outputs to an object storage of a digital twin platform, and to register access URLs and attribute mappings into a database schema of the digital twin platform.

2. The system of claim 1, wherein the BIM interface module is further configured to preserve pre-existing element identifiers or to generate provisional alphanumeric tags for building elements prior to IFC conversion, so as to maintain traceability between geometric and semantic data across processing stages.

3. The system of claim 2, wherein the IFC conversion module is further configured to perform schema-compliant type mapping, property normalization, and data serialization operations to align the BIM model with openBIM-based standards.

4. The system of claim 1, wherein the geometry conversion subcomponent is further configured to parse mesh elements consisting of vertices, edges, and faces, and to output a WebGL-compliant file format selected from glTF, JSON, or other WebGL-compliant-based geometry.

5. The system of claim 1, wherein the semantic structuring subcomponent is further configured to parse functional metadata including material type, element role, and associated properties, and to format the data into structured JSON, XML, or any other machine-readable documents.

6. The system of claim 1, wherein the IoT tagging subcomponent is further configured to:
generate a mesh representation from a BIM element identified as IoT-eligible;
compute a bounding box that tightly encloses the generated mesh representation;
calculate a centroid of the bounding box; and
package the centroid coordinates into a spatial tag associated with the identifier of the BIM element.

7. The system of claim 1, wherein the level tagging subcomponent is further configured to:
extract a mesh representation from a BIM element categorized as a floor element;
compute a bounding box that tightly encloses the extracted mesh representation;
identify the lowest z-coordinate point of the computed bounding box; and
assign a floor-level tag to the floor element based on the identified lowest z-coordinate point.

8. The system of claim 1, wherein the data linking module is further configured to:
generate and register access URLs for geometric and semantic files uploaded to the digital twin platform's object storage; and
format and store mappings between building element identifiers and associated metadata, including geometry file URLs, IFC categories, semantic tags, and level tags.

9. The system of claim 1, further comprising:
a digital twin synchronization module configured to retrieve updated content from the digital twin platform and update the stored BIM representation accordingly, wherein the digital twin synchronization module is further configured to monitor for changes to geometry, semantic attributes, or IoT associations in the digital twin platform.

10. The system of claim 1, wherein the system is implemented across one or more computing environments selected from cloud servers, edge computing units, or virtualized containers.

11. A method for integrating building information modeling (BIM) data with Internet of Things (IoT) data into a digital twin platform, thereby enabling real-time spatial monitoring, semantic referencing, and lifecycle management of building assets within a digital twin environment, the method comprising:
receiving, by a BIM interface module, external geometric and semantic data;
generating or updating, by the BIM interface module, a BIM model comprising three-dimensional representations of building elements and associated semantic specifications;
converting, by an industry foundation classes (IFC) conversion module, the BIM model into a format compliant with the an IFC schema so as to obtain a converted IFC model;
assigning, by the IFC conversion module, globally unique identifiers (GUIDs) to the building elements;
receiving, by a preprocessing module, the converted IFC model from the IFC conversion module;
performing, by the preprocessing module, model federation and data normalization, comprising:
transforming, by a geometry conversion subcomponent of the preprocessing module, BIM geometry into a format compatible with WebGL based on the geometric representations contained in the converted IFC model;
extracting and structuring, by a semantic structuring subcomponent of the preprocessing module, non-geometric metadata based on the semantic property sets contained in the converted IFC model;
computing, by an IoT tagging subcomponent of the preprocessing module, centroid-based spatial tags for IoT-eligible building elements based on the mesh geometry derived from the federated IFC model; and
computing, by a level tagging subcomponent of the preprocessing module, vertical placement information for IFC floor elements based on bounding box analysis of the floor-related geometry in the federated IFC model;
serializing, by a data linking module, geometric and semantic outputs from the preprocessing module;
uploading, by the data linking module, the geometric and semantic outputs to an object storage of a digital twin platform; and
registering, by the data linking module, access URLs and attribute mappings into a database schema of the digital twin platform.

12. The method of claim 11, further comprising:
preserving pre-existing element identifiers or generating provisional alphanumeric tags for building elements prior to IFC conversion, by using the BIM interface module, so as to maintain traceability between geometric and semantic data across processing stages.

13. The method of claim 12, further comprising:
performing, by the IFC conversion module, schema-compliant type mapping, property normalization, and data serialization operations to align the BIM model with openBIM-based standards.

14. The method of claim 11, further comprising:
parsing, by the geometry conversion subcomponent, mesh elements consisting of vertices, edges, and faces; and
outputting, by the geometry conversion subcomponent, a WebGL-compliant file format selected from glTF or JSON or other WebGL-compliant formats-based geometry.

15. The method of claim 11, further comprising:
parsing, by the semantic structuring subcomponent, functional metadata including material type, element role, and associated properties; and
formatting, by the semantic structuring subcomponent, the data into structured JSON, XML, or any other machine-readable documents.

16. The method of claim 11, further comprising:
generating, by the IoT tagging subcomponent, a mesh representation from a BIM element identified as IoT-eligible;
computing, by the IoT tagging subcomponent, a bounding box that tightly encloses the generated mesh representation;
calculating, by the IoT tagging subcomponent, a centroid of the bounding box; and
packaging, by the IoT tagging subcomponent, the centroid coordinates into a spatial tag associated with the identifier of the BIM element.

17. The method of claim 11, further comprising:
extracting, by the level tagging subcomponent, a mesh representation from a BIM element categorized as a floor element;
computing, by the level tagging subcomponent, a bounding box that tightly encloses the extracted mesh representation;
identifying, by the level tagging subcomponent, the lowest z-coordinate point of the computed bounding box; and
assigning, by the level tagging subcomponent, a floor-level tag to the floor element based on the identified lowest z-coordinate point.

18. The method of claim 11, further comprising:
generating and registering, by the data linking module, access URLs for geometric and semantic files uploaded to the digital twin platform's object storage; and
formatting and storing, by the data linking module, mappings between building element identifiers and associated metadata, including geometry file URLs, IFC categories, semantic tags, and level tags.

19. The method of claim 11, further comprising:
retrieving, by a digital twin synchronization module, updated content from the digital twin platform;
updating, by the digital twin synchronization module, the stored BIM representation accordingly; and
monitoring, by the digital twin synchronization module, for changes to geometry, semantic attributes, or IoT associations in the digital twin platform.

20. The method of claim 11, wherein the method is performed on one or more computing environments selected from cloud servers, edge computing units, or virtualized containers.
